(19) United States
(12) Patent Application Publication
(10) Pub. No.: US 2008/0025005 A1
(43) Pub. Date: Jan. 31, 2008

(54) HAND-HELD DEVICE ENCLOSURE

(75) Inventors: Te-Yao Yeh, Shenzhen (CN); Mo-Liang Li, Shenzhen (CN); Jin-Sheng Huang, Shenzhen (CN)

Correspondence Address: NORTH AMERICA INTELLECTUAL PROPERTY CORPORATION, P.O. BOX 506, MERRIFIELD, VA, 22116, US

(73) Assignee: HON HAI PRECISION INDUSTRY CO., LTD., Taipei Hsien (TW)

(21) Appl. No.: 11/621,122

(22) Filed: Jan. 9, 2007

(30) Foreign Application Priority Data
Jul. 26, 2006 (CN) 200610061817.5

(51) Int. Cl. H05K 5/00

(52) U.S. Cl. 361/752

(57) ABSTRACT

A hand-held device enclosure is disclosed. The hand-held device includes a front cover, a back cover, and a frame. The frame defines a plurality of honeycomb holes therein, is configured for fixing a printed circuit board, and is interposed between the front cover and the back cover. The front cover, the back cover, and the frame are connected using screws. The enclosure has good structural strength and is light because of the honeycomb structure.

### BACKGROUND

1. Technical Field

The present invention relates to a hand-held device enclosure.

2. General Background

Ever since hand-held devices, such as mobile phones, personal digital assistants, electronic books, etc, have been introduced, they have become smaller and lighter. The hand-held devices consist of an enclosure, a printed circuit board (abbreviated as PCB), and electronic components. If weight of the enclosures is reduced, total weight of the hand-held devices would be reduced too.

Honeycomb structured support is good in structural strength and is light in weight. For example, CN patent No. 00,210,037 (issued on Nov. 28, 2001) discloses a vehicle/ship enclosure with a frame. The frame has a honeycomb structure. The enclosure is light in weight. However, the honeycomb structure is not used in hand-held devices yet. The hand-held device usually adopts light materials to reduce weight.

Therefore, what is needed is a hand-held device enclosure having honeycomb structure.

### SUMMARY

A hand-held device is disclosed. The hand-held device includes a front cover, a back cover, and a frame. The frame defines a plurality of honeycomb holes therein, is configured for fixing a printed circuit board, and is interposed between the front cover and the back cover. The front cover, the back cover, and the frame are connected using screws.

Other advantages and novel features will be drawn from the following detailed description with reference to the attached drawing, in which:

### BRIEF DESCRIPTION OF THE DRAWINGS

FIG. 1 is a schematic, solid view of a hand-held device enclosure according to a preferred embodiment of the present invention;

FIG. 2 is a exploded view of the hand-held device enclosure of FIG. 1;

FIG. 3 is a schematic, solid view of a back cover of the hand-held device enclosure of FIG. 1; and

FIG. 4 is a schematic, solid view of a frame of the hand-held device enclosure of FIG. 1.

### DETAILED DESCRIPTION OF THE EMBODIMENT

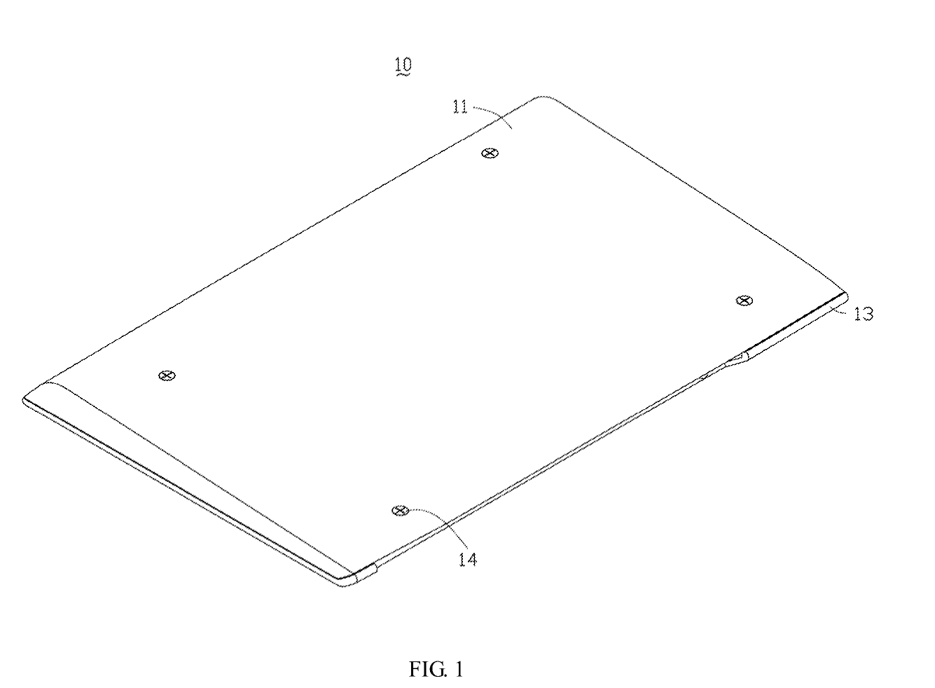

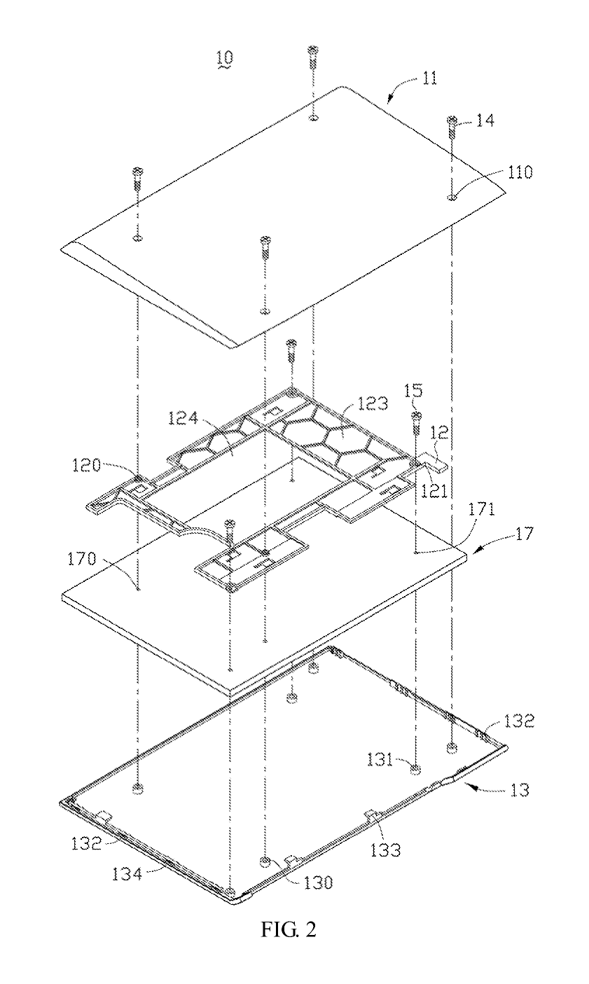

Referring to FIGS. 1 and 2, a hand-held device enclosure 10 is disclosed. The hand-held device enclosure 10 includes a front cover 13, a frame 12, and a back cover 11. The frame 12 is disposed between the front cover 13 and the back cover 11. A printed circuit board (PCB) 17 is disposed between the front cover 13 and the back cover 11. The PCB 17 is configured for supporting a liquid crystal display (LCD) and electronic components.

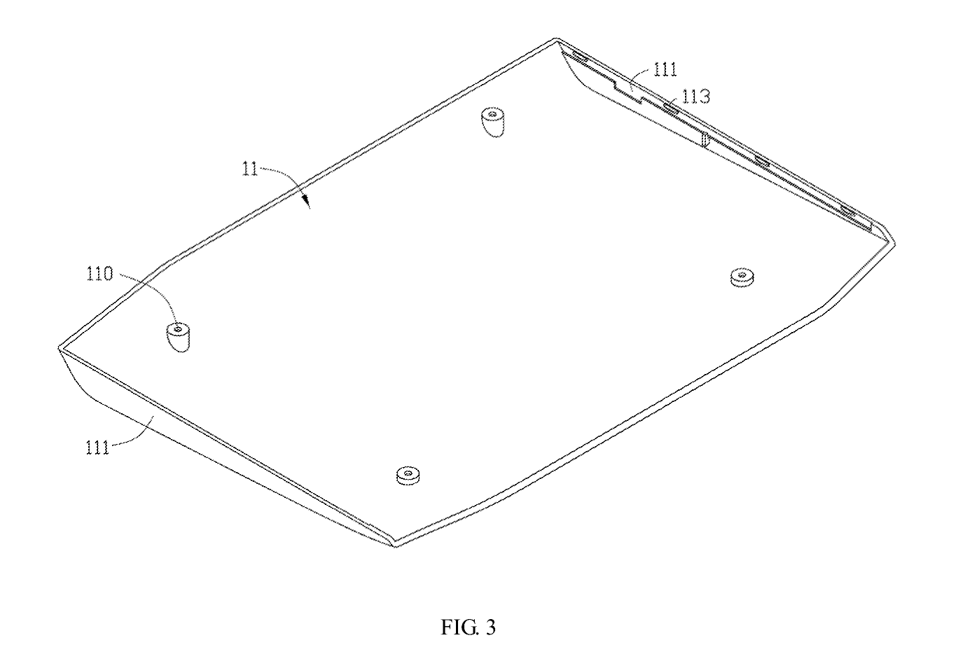

Referring to FIGS. 2 and 3, the front cover 13 defines a plurality of buckle bases 132 on two ends. Each of the buckle bases 132 defines a groove 134. The front cover 13 also defines buckles 133 on a side so as to fix the PCB 17.

Outer walls 111 extends from Opposite ends of the back cover 111. Each of the outer walls 111 defines a plurality of buckles 113 to be wedged into the grooves 134 of the front cover 13.

The front cover 13 and the back cover 111 may also define an opening to receive the LCD, and a groove to receive batteries. Plastic material is adopted to produce the front cover 13 and the back cover 11.

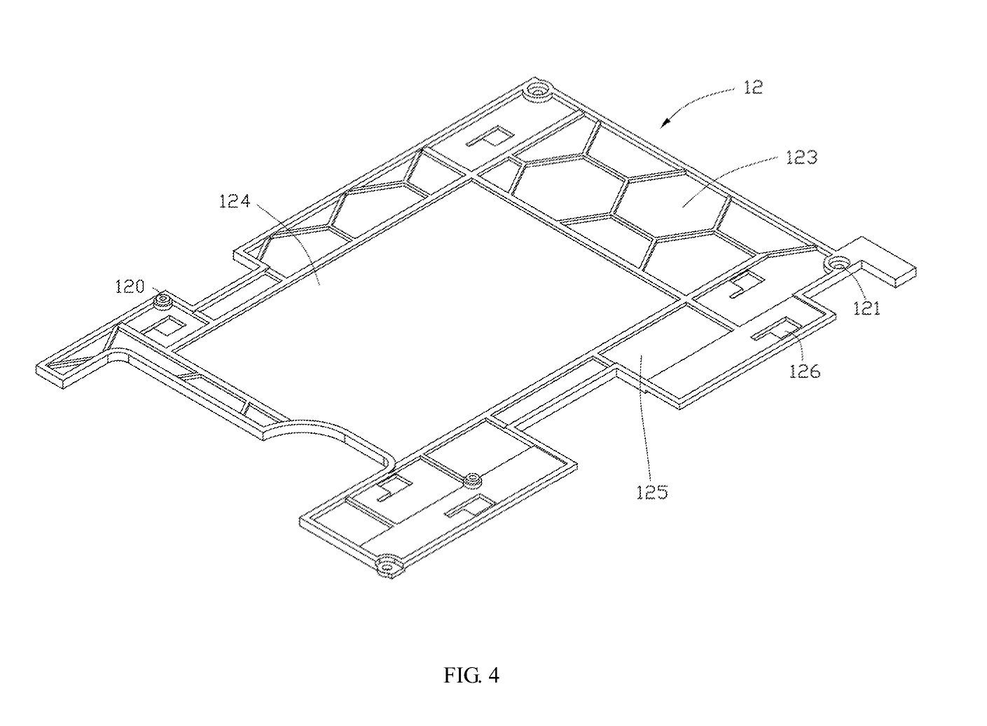

Referring to FIG. 4, the PCB 17 is equipped with the LCD and the electronic components. Therefore, the frame 12 must be strong enough to support the PCB 17, the LCD, and the electronic components. The frame 12 is made by light alloy material such as magnesium alloy material. The frame 12 defines an opening 124 in the middle section. The frame 12 also defines blind holes 125, through holes 126, and honeycomb holes 123 in the outer section of the frame 12 and around the opening 124. The honeycomb holes 123 may be blind holes or through holes. It is known that a honeycomb structure has advantages of good structural strength and a relatively light weight. Therefore, the frame 12 has good structural strength and relatively light weight because of the honeycomb structure.

Referring to FIGS. 1and 2, screws 14 pass through screw holes 110 in the back cover 11 and screw holes 130 in the front cover 13, so as to connect the back cover 11 and the front cover 13 together. Parts of the screws 14 extend through screw holes 170 in the PCB 17 and screw holes 120 in the frame 12. Screws 15 pass through screw holes 171 in the PCB 17, screw holes 121 in the frame 12, and screw holes 111 in the front cover 13, and thus connect the PCB 17, the frame 12, and the front cover 13 together.

Although the present invention has been specifically described on the basis of a preferred embodiment and preferred method thereof, the invention is not to be construed as being limited thereto. Various changes or modifications may be made to the embodiment and method without departing from the scope and spirit of the invention.

What is claimed is:

1. A hand-held device enclosure comprising:
a front cover;
a back cover; and
a frame interposed between the front cover and the back cover, the frame being configured for supporting a printed circuit board, the frame defining a plurality of honeycomb holes therein;
wherein the front cover, the back cover, and the frame are connected using screws.

2. The hand-held device enclosure of claim 1, wherein the frame is comprised of light alloy material.

3. The hand-held device enclosure of claim 2, wherein the light alloy is magnesium alloy.

4. The hand-held device enclosure of claim 1, wherein the honeycomb holes are blind holes.

5. The hand-held device enclosure of claim 1, wherein the honeycomb holes are through holes.

6. The hand-held device enclosure of claim 1, wherein the front cover and the back cover are comprised of plastic.

7. The hand-held device enclosure of claim 1, wherein the front cover and the back cover are mechanically engaged with each other.
